(19) United States
(12) Patent Application Publication
(10) Pub. No.: US 2026/0269654 A1
(43) Pub. Date: Sep. 10, 2026

(54) SELF-RECHARGING ELECTRONIC DEVICE

(71) Applicant: Quanta Computer Inc., Taoyuan City (TW)

(72) Inventor: Hsin-Liang LIN, Taoyuan City (TW)

(21) Appl. No.: 19/188,269

(22) Filed: Apr. 24, 2025

(30) Foreign Application Priority Data
Mar. 5, 2025 (TW) 114108051

(51) Int. Cl. H02J 50/30; H02J 50/00; H05K 7/20

(52) U.S. Cl. CPC H02J 50/30; H02J 50/001; H05K 7/20136; H05K 7/20209

(57) ABSTRACT

A self-recharging electronic device is provided, including a charge integrated circuit (IC), a controller, a light coupler, and a signal converter. The charger IC is coupled to an inner power supply to charge or discharge the inner power supply. The controller is coupled to the charger IC and is configured to output a control signal to a heat dissipation device. The light coupler is configured to generate a first signal through a light source and the heat dissipation device. The signal converter is configured to generate an output voltage corresponding to the period of the first signal, wherein the charger IC uses the output voltage to charge the inner power supply.

### CROSS REFERENCE TO RELATED APPLICATIONS

This Application claims priority of Taiwan Patent Application No. 114108051, filed on March 5, 2025, the entirety of which is incorporated by reference herein.

### BACKGROUND OF THE INVENTION

### Field of the Invention

The present invention relates to a rechargeable electronic device, in particular, to an electronic device that can be recharged by itself.

### Description of the Related Art

As portable devices are increasingly integrated into daily life, the issue of their battery life has gradually garnered significant attention. Furthermore, the diversification of functionalities has led to portable devices being used more frequently to execute power-intensive applications, resulting in increased power consumption and shortened usage time. Generally, extending the usage time of portable devices can be achieved by replacing them with higher-capacity batteries or carrying additional charging accessories (such as power banks or charging cables). However, larger batteries may lead to increased design costs or create safety concerns, and carrying additional charging accessories may cause the user to encounter problems such as the unavailability of power outlets for charging or insufficient remaining battery power in the charging device itself.

### BRIEF SUMMARY OF THE INVENTION

According to the embodiment of this disclosure, a self-recharging electronic device is provided, including a charging integrated circuit, a controller, a photoelectric coupling element and a signal converter. The charging integrated circuit is coupled to an internal power supply to charge or discharge the internal power supply. The controller is coupled to the charging integrated circuit, and is configured to output a control signal to a heat dissipation device. The photoelectric coupling element is configured to generate a first signal through a light source and the heat dissipation device, the signal converter is configured to generate an output voltage corresponding to the period of the first signal. Wherein the charging integrated circuit utilizes the output voltage to charge the internal power supply.

According to one of the embodiments of this disclosure, the photoelectric coupling element includes a light-emitting part and a light-receiving part, the light-emitting part is configured to project a light emitted by the light source onto the light-receiving part, the light-receiving part is configured to generate the first signal according to the light emitted by the light source. Wherein the heat dissipation device periodically blocks the light-receiving part from receiving the light emitted by the light source to generate the first signal having periodic level changes.

According to one of the embodiments of this disclosure, the light source is the existing light source of the self-recharging electronic device.

According to one of the embodiments of this disclosure, the controller is configured to output the control signal to drive the heat dissipation device to dissipate heat when the self-recharging electronic device reaches a heat dissipation standard. When the heat dissipation efficiency of the heat dissipation device is higher, the period of the first signal is shorter, and the voltage value of the output voltage is higher.

According to one of the embodiments of the disclosure, the self-recharging electronic device further including a voltage converter is coupled between the signal converter and the charging integrated circuit, and is configured to amplify the output voltage.

According to one of the embodiments of this disclosure, wherein the heat dissipation device is a fan, and the first signal is a pulse width modulation signal.

### BRIEF DESCRIPTION OF THE DRAWINGS

This disclosure, the advantages and drawings of this disclosure will be easier to understand from the description of the representative embodiments that follow and refer to the accompanying drawings. These drawings describe only representative embodiments and should not be construed as a limitation of the various embodiments or claims.

FIG. 1 shows a block diagram of a self-recharging electronic device according to one of the embodiments of this disclosure;

FIG. 2A shows a schematic diagram of a photoelectric coupling element according to one of the embodiments of this disclosure;

FIG. 2B shows an example of a light-emitting part and a light-receiving part of the photoelectric coupling element in FIG. 2A;

FIG. 3A and FIG. 3B show the timing diagrams of a pulse width modulation signal with different periods at different system performance.

### DETAILED DESCRIPTION OF THE INVENTION

Reference will now be made in detail to the accompanying drawings to describe various embodiments, wherein like reference numerals refer to like or equivalent elements throughout the several views. The drawings are not necessarily drawn to scale, and are merely illustrative of aspects and features of the present disclosure. Numerous specific details, relationships, and methods are set forth to provide a thorough understanding of specific aspects and features of the present disclosure; however, those skilled in the relevant art will appreciate that these aspects and features can be practiced without one or more of the specific details, with other relationships, or by using other methods. In other instances, well-known structures or operations are not shown in detail for the purpose of clarity. The multiple embodiments disclosed herein are not necessarily limited to the sequence of actions or events schematically illustrated, as some actions may occur in different sequences and/or concurrently with other actions or events. Furthermore, not all schematically illustrated actions are required to implement particular aspects and features of the present disclosure.

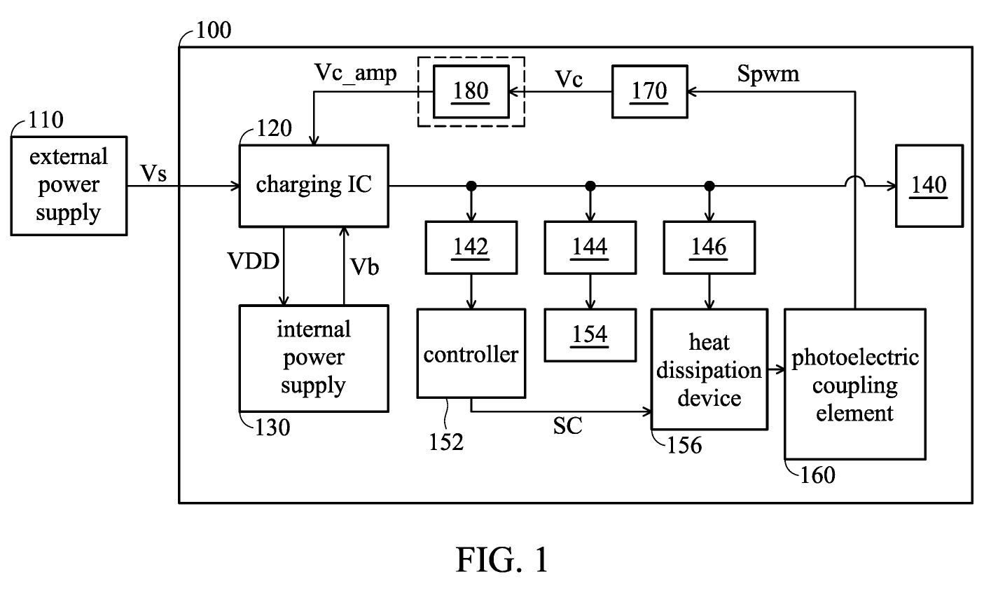

FIG. 1 shows a block of a self-recharging electronic device 100 according to one of the embodiments of this disclosure, wherein the self-recharging electronic device 100 includes a charging circuit and a discharge circuit. The charging circuit includes an external supply voltage Vs, an internal supply voltage Vb, and an amplified voltage Vc_amp, wherein the external supply voltage Vs is input from an external power supply 110 to a charging integrated circuit (IC) 120, the internal supply voltage Vb of the charging IC 120 is output from an internal power supply 130, and the amplified voltage Vc_amp from a photoelectric coupling element 160, through a pulse width modulation (PWM) signal converter 170 and a voltage converter 180, is output to the charging IC 120. If the voltage value of an output voltage Vc output by the PWM signal converter 170 is sufficient (e.g., the internal power supply 130 can be charged with the voltage value of the output voltage Vc through the charging IC 120), the voltage converter 180 is not required to amplify the output voltage Vc, and the output voltage Vc is directly output to the charging IC 120 through the PWM signal converter 170.

The discharging circuit of the self-recharging electronic device 100 includes a voltage converter 142, a voltage converter 144, a rectifier 146, and a charging IC 120, wherein the voltage converter 142 and the voltage converter 144 supply power to a controller 152 and an internal circuit 154 respectively, the rectifier 146 supplies power to a heat dissipation device 156, and the charging IC 120 drives the voltage converter 142 and the voltage converter 144, the rectifier 146 and a display 140. The self-recharging circuit of the self-recharging electronic device 100 includes at least a controller 152, a heat dissipation device 156, a photoelectric coupling element 160 and a PWM signal converter 170. If the output voltage Vc of the PWM signal converter 170 is not sufficient to enable the charging IC 120 to charge the internal power supply 130, the self-recharging circuit further includes a voltage converter 180 for amplifying the output voltage Vc into an amplification voltage Vc_amp. With reference to the FIG. 1, the external power supply 110 can be an external charging device (e.g., a mobile power supply) or a charging cable connected to other power sources to charge the self-recharging electronic device 100, the internal power supply 130 can be a battery of the self-recharging electronic device 100, and the heat dissipation device 156 can be a cooling fan of the self-recharging electronic device 100.

When the operating efficiency of the self-recharging electronic device 100 reaches a heat dissipation standard (e.g., the internal temperature rises to a threshold), the controller 152 can output a control signal SC to the heat dissipation device 156 to drive the heat dissipation device 156 to start dissipating heat (e.g., cooling down) from the self-recharging electronic device 100. For example, in one of the embodiments, the heat dissipation device 156 is a system fan. Therefore, the control signal SC drives the heat dissipation device 156 to start rotating. The more operating efficiency of the self-recharging electronic device 100 exceeds the heat dissipation standard, the higher the operating efficiency of the heat dissipation device 156 (e.g., the faster the fan rotation) in order to restore the internal temperature to the threshold as soon as possible.

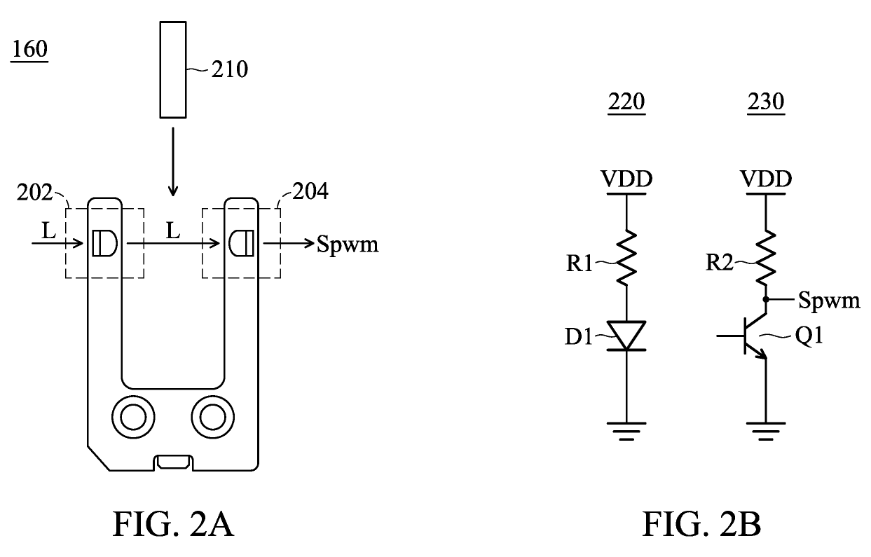

According to the different operating efficiency of the self-recharging electronic device 100, the control signal SC output by the controller 152 will control the heat dissipation device 156 at different fan speeds. By combining the heat dissipation device 156 with the photoelectric coupling element 160, a PWM signal Spwm can be generated through whether the light source inside the self-recharging electronic device 100 is blocked by a fan blade, and then a voltage and/or current for subsequently charging the internal power supply 130 is generated. The detailed charging process will be illustrated as follows with reference to FIG. 2A and FIG. 2B.

FIG. 2A shows a schematic diagram of a photoelectric coupling element 160 according to the present disclosed embodiment, and FIG. 2B shows an example of a light-emitting part 202 and a light-receiving part 204 of the photoelectric coupling element 160 in FIG. 2A. As shown in FIG. 2A, the photoelectric coupling element 160 includes a light-emitting part 202 and a light-receiving part 204, and there is a certain interval between the two, so that a detector object 210 can pass between the light-emitting part 202 and the light-receiving part 204 without touching the light-emitting part 202 and the light-receiving part 204. The light-emitting part 202 can receive a light L emitted by an internal light source (e.g., a light-emitting diode D1 in FIG. 2B) of a self-recharging electronic device 100 and project it to the light-receiving part 204 (e.g., a phototransistor (light-sensing transistor) Q1 in FIG. 2B) to generate a PWM signal Spwm.

Suppose that when the light-receiving part 204 successfully receives the light L from the light-emitting part 202, the PWM signal Spwm has a first logical level (e.g., logic 0), and when the light-receiving part 204 does not receive the light L (e.g., the light L is blocked by the detector object 210), the PWM signal Spwm has a second logical level (e.g., logic 1). In one of the embodiments, the heat dissipation device 156 can be a system fan, so the detector object 210 in FIG. 2A can be a blade of the system fan. When the self-recharging electronic device 100 meets the heat dissipation standard, the controller 152 drives the fan blades of the heat dissipation device 156 to rotate through the control signal SC.

When the fan blade rotates between the light-emitting part 202 and the light-receiving part 204, the blade blocks the light L, and then generates a PWM signal Spwm with a second logical level (e.g., logic 1). When the fan is rotated to the blade gap between the light-emitting part 202 and the light-receiving part 204, the light L is not blocked, and then a PWM signal Spwm with the first logical level (e.g., logic 0) is generated. Thus, the heat dissipation device 156 periodically (e.g., when the fan rotates at a fixed speed) blocks the light L projected from the light-emitting part 202 to the light-receiving part 204, and then generates the PWM signal Spwm that periodically changes between the first logical level and the second logical level.

Then, with reference to FIG. 2B, a light-emitting element 220 and a light-receiving element 230 are shown, wherein the light-emitting element 220 is an example of the light-emitting part 202 of the photoelectric coupling element 160, and the light-receiving element 230 is an example of the light-receiving part 204 of the photoelectric coupling element 160, and this disclosure is not limited to this. The light-emitting element 220 includes a resistor R1 and a light-emitting diode D1 connected in series between a supply voltage VDD and a ground terminal. The light-emitting element 220 can be the existing light source (e.g., system internal lighting, display lamp, etc.) of the self-recharging electronic device 100, and is configured to project light L to the light-receiving part 204 through the light-emitting part 202. The light-receiving element 230 includes a resistor R2 and a phototransistor Q1 connected in series between the supply voltage VDD and the grounding terminal. The light-receiving element 230 is configured to receive light L and convert it into a PWM signal Spwm with a logical level change (e.g., between logic 0 and logic 1).

As mentioned in FIG. 1 above, the fan of the heat dissipation device 156 is driven only after the self-recharging electronic device 100 has reached the heat dissipation standard. Therefore, the fan of the heat dissipation device 156 will not periodically block the light L until the self-recharging electronic device 100 has reached the heat dissipation standard. In other words, the PWM signal Spwm does not have periodic logical level changes until the self-recharging electronic device 100 meets the heat dissipation standard. Assuming that the fan does not block the light L when it is stopped, the charging circuit including the photoelectric coupling element 160 and the PWM signal converter 170 (as well as the voltage converter 180) will not charge the internal power supply 130 until the self-recharging electronic device 100 meets the heat dissipation standard.

Specifically, the self-recharging electronic device 100 does not meet the heat dissipation standard, and it can also be regarded that the self-recharging electronic device 100 does not meet the power consumption threshold that requires self-recharging. Therefore, disabling the charging circuit when it is not necessary to activate the charging circuit for self-recharging can also save the power consumption required to activate the charging circuit and further extend the service life of the self-recharging electronic device100.

In addition, since the light-emitting element 220 (or the light-emitting part 202) can be part of the original circuit of the self-recharging electronic device 100 (i.e., it may be part of the internal circuit 154), the light source used to generate the PWM signal Spwm does not need to consume additional power consumption when driving the self-recharging circuit.

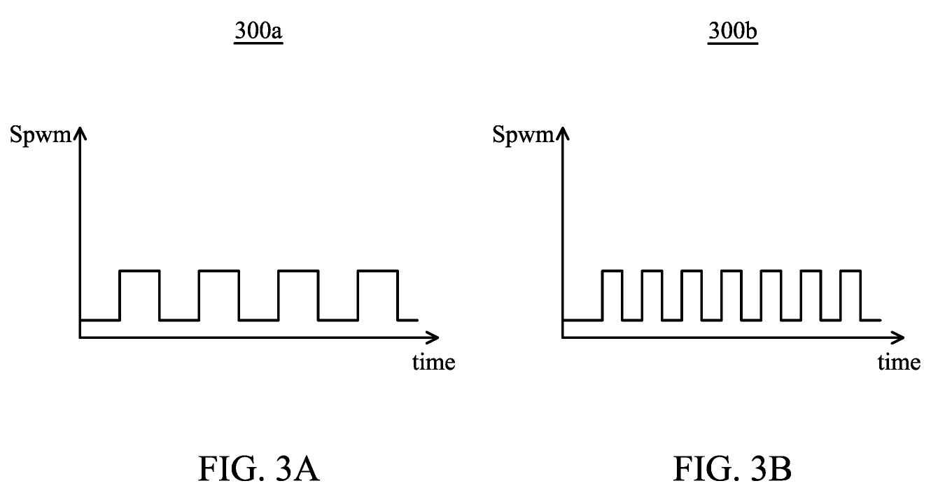

FIG. 3A and FIG. 3B show the timing diagram 300a and timing diagram 300b of PWM signals with different periods under different operating performance, respectively. Referring to FIG. 3A, the timing diagram 300a shows the waveform of the PWM signal Spwm generated by the photoelectric coupling element 160 when the self-recharging electronic device 100 meets the heat dissipation standard but the power consumption is low. Referring to FIG. 3B, the timing diagram 300b shows the waveform of the PWM signal Spwm generated by the photoelectric coupling element 160 when the self-recharging electronic device 100 meets the heat dissipation standard but the power consumption is high.

Comparing the timing diagram 300a with the timing diagram 300b, it can be determined that when the self-recharging electronic device 100 meets the heat dissipation standard and the power consumption is high (as shown in the timing diagram 300b), the PWM signal Spwm has a dense pulse wave (i.e., a shorter period) due to the faster fan speed. When the self-recharging electronic device 100 meets the heat dissipation standard and the power consumption is low (as shown in the timing diagram 300a), the PWM signal Spwm has a looser pulse wave (i.e., longer period) due to the slower fan speed. When converting a PWM signal to a voltage, the larger the proportion of time that the PWM signal remains at a high logic level (e.g., logic 1) per unit of time, the higher the converted voltage will be. As a result, the denser PWM signal Spwm will convert the output signal Vc with a higher voltage level.

Therefore, when the PWM signal converter 170 converts the PWM signal Spwm into the output voltage Vc, the output voltage Vc obtained by the timing diagram 300b has a higher voltage than the output voltage Vc obtained by the timing diagram 300a. In other words, when the power consumption of the self-recharging electronic device 100 is higher, the supply voltage VDD generated by the self-charging circuit for recharging the internal power supply 130 is also higher, and the usage time can be extended in response to the different power consumption of the self-recharging electronic device 100.

For example, if the internal power supply 130 has a capacity of 47 mAH, then when the self-recharging electronic device 100 operates under the power consumption of the heat dissipation standard, such as using a current of 4.7 mA, the total usage time without charging circuit is 47/4.7 = 10 hours. However, in the case of with a charging circuit, such as through a heat dissipation device 156, a photoelectric coupling element 160, and a PWM signal converter 170 (and a voltage converter 180) that can generate a 1mA recharge current of 1 mA, the total usage time at this time is 47/(4.7-1) = 12.7 hours, which is about 2.7 hours longer (i.e., about 27% longer).

It should be noted that after the photoelectric coupling element 160 generates a PWM signal Spwm and it is converted into an output voltage Vc, and then converted into a corresponding current by other voltage-to-current converter (not shown) or amplified by a voltage converter 180, the real recharge current and/or voltage is obtained by subtracting the electrical energy consumed during the conversion period.

By implementing the self-recharging electronic device provided in this disclosure in a portable device, when the operating efficiency of the system reaches the standard of starting the charging circuit for internal power supply (e.g., the battery) recharges (e.g., the internal temperature rises to a certain threshold), the charging circuit can be driven to generate a voltage or current equivalent to the charging voltage or charging current of the internal power supply, so that the power consumption of the battery is reduced, and the residual power decreases slower than that of the device without a charging circuit to extend the total usage time.

What is claimed is:

1. A self-recharging electronic device, comprising:
a charging integrated circuit, coupled to an internal power supply to charge or discharge the internal power supply;
a controller, coupled to the charging integrated circuit, and configured to output a control signal to a heat dissipation device;
a photoelectric coupling element, configured to generate a first signal through a light source and the heat dissipation device; and
a signal converter, configured to generate an output voltage corresponding to a period of the first signal,
wherein the charging integrated circuit utilizes the output voltage to charge the internal power supply.

2. The self-recharging electronic device as claimed in claim 1, wherein the photoelectric coupling element comprises:
a light-emitting part and a light-receiving part, wherein the light-emitting part is configured to project a light emitted by the light source onto the light-receiving part, and the light-receiving part is configured to generate the first signal according to the light emitted by the light source,
wherein the heat dissipation device periodically blocks the light-receiving part from receiving the light emitted by the light source to generate the first signal having periodic level changes.

3. The self-recharging electronic device as claimed in claim 2, wherein the light-emitting part is a light-emitting diode.

4. The self-recharging electronic device as claimed in claim 3, wherein the light-emitting diode is the light source of the self-recharging electronic device.

5. The self-recharging electronic device as claimed in claim 2, wherein the light-receiving part is a phototransistor.

6. The self-recharging electronic device as claimed in claim 1, wherein the controller is configured to output the control signal to drive the heat dissipation device to dissipate heat when the self-recharging electronic device reaches a heat dissipation standard.

7. The self-recharging electronic device as claimed in claim 6, wherein when a heat dissipation efficiency of the heat dissipation device is higher, the period of the first signal is shorter, and a voltage value of the output voltage is higher.

8. The self-recharging electronic device as claimed in claim 1, further comprising a voltage converter coupled between the signal converter and the charging integrated circuit, and configured to amplify the output voltage.

9. The self-recharging electronic device as claimed in claim 1, wherein the heat dissipation device is a fan.

10. The self-recharging electronic device as claimed in claim 1, wherein the first signal is a pulse width modulation signal.
